(19) United States
(12) Patent Application Publication
(10) Pub. No.: US 2024/0128936 A1
(43) Pub. Date: Apr. 18, 2024

(54) POWER AMPLIFIER CIRCUIT AND COMMUNICATION DEVICE

(71) Applicant: Murata Manufacturing Co., Ltd., Nagaokakyo-shi (JP)

(72) Inventors: Kenji TAHARA, Nagaokakyo-shi (JP); Ryo WAKABAYASHI, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/394,165

(22) Filed: Dec. 22, 2023

Related U.S. Application Data
(63) Continuation of application No. PCT/JP2022/026486, filed on Jul. 1, 2022.

(30) Foreign Application Priority Data
Jul. 7, 2021 (JP) 2021-113127

(51) Int. Cl. H03F 1/30; H03F 1/02; H03F 3/195; H03F 3/24

(52) U.S. Cl. CPC H03F 1/302; H03F 1/0222; H03F 3/195; H03F 3/245; H03F 2200/102; H03F 2200/451

(57) ABSTRACT

A power amplifier circuit includes an amplifier transistor having a collector terminal, an emitter terminal, and a base terminal, bias circuits, and a current limiter circuit. The bias circuit includes a constant current amplifier transistor that supplies direct-current bias current from an emitter terminal to the base terminal. The current limiter circuit includes a current limiting transistor an emitter terminal of which is connected to the bias circuit, a resistive element connected between the current limiting transistor and a power supply terminal, and a resistive element connected between the current limiting transistor and the constant current amplifier transistor. The bias circuit includes a constant current amplifier transistor that supplies direct-current bias current i3 from an emitter terminal to the base terminal.

### CROSS-REFERENCE TO RELATED APPLICATIONS

This application is a continuation of international application no. PCT/JP2022/026486, filed Jul. 1, 2022, and which claims priority to Japanese application no. JP 2021-113127, filed Jul. 7, 2021. The entire contents of both prior applications are hereby incorporated by reference.

### TECHNICAL FIELD

The present disclosure relates to a power amplifier circuit and a communication device.

### BACKGROUND ART

Improvement of power-added efficiency is attempted by varying power supply voltage to be supplied to a power amplifier circuit in recent years. A technique of analog envelope tracking (ET) to supply the power supply voltage of a continuously varying voltage level, a technique of average power tracking (APT) to supply the power supply voltage of multiple discrete voltage levels, and so on are known.

### CITATION LIST

### Patent Document

Patent Document 1: U.S. Patent Application Publication No. 2020/0076375

### SUMMARY

### Technical Problem

However, when the gain of the power amplifier circuit is varied due to the variation of the power supply voltage to be supplied to the power amplifier circuit, the quality of a radio-frequency signal output from the power amplifier circuit may be reduced.

In order to resolve the above problem, the present disclosure provides a power amplifier circuit and a communication device, which are capable of suppressing reduction in quality of the radio-frequency output signal when the power supply voltage to be supplied to the power amplifier circuit is varied.

### Solution to Problem

A power amplifier circuit according to one aspect of the present disclosure includes a power supply terminal; a first amplifier transistor that has a first terminal connected to the power supply terminal, a second terminal, and a first control terminal and that performs power amplification to a radio-frequency input signal input from the first control terminal to output a radio-frequency signal resulting from the power amplification from the first terminal; a first bias circuit that outputs first direct-current bias current; a second bias circuit that outputs second direct-current bias current; and a modulation circuit. The first bias circuit includes a first transistor that has a third terminal, a fourth terminal, and a second control terminal and that supplies the first direct-current bias current from the fourth terminal to the first control terminal. The modulation circuit includes a second transistor which has a fifth terminal, a sixth terminal, and a third control terminal and the sixth terminal of which is connected to the fourth terminal, a first resistive element connected between the fifth terminal and the power supply terminal, and a second resistive element connected between the third control terminal and the second control terminal. The second bias circuit includes a third transistor that has a seventh terminal, an eighth terminal, and a fourth control terminal and that supplies the second direct-current bias current from the eighth terminal to the first control terminal.

A power amplifier circuit according to one aspect of the present disclosure includes a power supply terminal; a first amplifier transistor to which power supply voltage is supplied from the power supply terminal and which performs power amplification to a radio-frequency input signal; a first bias circuit that supplies first direct-current bias current to the first amplifier transistor; a second bias circuit that supplies second direct-current bias current to the first amplifier transistor; a modulation circuit that is connected to the first bias circuit and the first amplifier transistor and that varies a magnitude of the first direct-current bias current in accordance with a magnitude of the power supply voltage; and a control circuit that switches between the supply of the first direct-current bias current to the first amplifier transistor and the supply of the second direct-current bias current to the first amplifier transistor a channel bandwidth of the radio-frequency input signal.

A power amplifier circuit according to one aspect of the present disclosure includes a power supply terminal; a first amplifier transistor that has a first terminal connected to the power supply terminal, a second terminal, and a first control terminal and that performs power amplification to a radio-frequency input signal input from the first control terminal to output a radio-frequency signal resulting from the power amplification from the first terminal; a first bias circuit that outputs first direct-current bias current; and a modulation circuit. The first bias circuit includes a first transistor that has a third terminal, a fourth terminal, and a second control terminal and that supplies the first direct-current bias current from the fourth terminal to the first control terminal. The modulation circuit includes a second transistor that has a fifth terminal, a sixth terminal, and a third control terminal, a first resistive element connected between the fifth terminal and the power supply terminal, a second resistive element connected between the third control terminal and the second control terminal, and a first switch which has a seventh terminal and an eighth terminal, the seventh terminal of which is connected to the sixth terminal, and the eighth terminal of which is connected to the fourth terminal.

### Exemplary Advantageous Effects

With the power amplifier circuit according to an aspect of the present disclosure, it is possible to suppress reduction in quality of the radio-frequency output signal when the power supply voltage to be supplied to the power amplifier circuit is varied.

### BRIEF DESCRIPTION OF DRAWINGS

FIG. 1 is a diagram illustrating a circuit configuration of a power amplifier circuit and a communication device according to an exemplary embodiment.

FIG. 2 is a circuit block diagram of the power amplifier circuit and a power supply circuit according to the exemplary embodiment.

FIG. 3 is a diagram illustrating a circuit configuration of a power amplifier according to the exemplary embodiment.

FIG. 4A is a graph indicating the relationship between output power and gain in an analog ET mode.

FIG. 4B is a graph indicating one example of transition of power supply voltage in the analog ET mode.

FIG. 5A is a graph indicating the relationship between the output power and the gain in an APT mode.

FIG. 5B is a graph indicating one example of transition of the power supply voltage in the APT mode.

FIG. 6A is a diagram illustrating the circuit state in the analog ET mode of the power amplifier circuit and the power supply circuit according to the exemplary embodiment.

FIG. 6B is a diagram illustrating the circuit state in the APT mode of the power amplifier circuit and the power supply circuit according to the exemplary embodiment.

FIG. 7A is a diagram illustrating the circuit state in the analog ET mode of a power amplifier according to a modification of the exemplary embodiment.

FIG. 7B is a diagram illustrating the circuit state in the APT mode of the power amplifier according to the modification of the exemplary embodiment.

FIG. 8A is a plan view of a radio-frequency module according to an example.

FIG. 8B is a cross-sectional view of the radio-frequency module according to the example.

### DETAILED DESCRIPTION

Exemplary embodiments of the present disclosure will herein be described in detail with reference to the drawings. All the exemplary embodiments described below indicate comprehensive or specific examples. Numerical values, shapes, materials, components, the arrangement of the components, the connection mode of the components, and so on, which are indicated in the exemplary embodiments described below, are only examples and are not intended to limit the present disclosure.

The respective drawings are schematic diagrams appropriately subjected to emphasis, omission, or adjustment of ratios in order to describe the present disclosure. The respective drawings are not necessarily strictly illustrated and may be different from the actual shapes, positional relationship, and ratios. The same reference numerals are used in the respective drawings to identify substantially the same components and a duplicated description of such components may be omitted or simplified.

In the respective drawings described below, the x axis and the y axis are axes that are orthogonal to each other on a plane parallel to main surfaces of a module laminate. Specifically, when the module laminate has a rectangular shape in a plan view, the x axis is parallel to a first side of the module laminate and the y axis is parallel to a second side orthogonal to the first side of the module laminate. The z axis is an axis vertical to the main surfaces of the module laminate. The positive direction of the z axis indicates the upward direction and the negative direction thereof indicates the downward direction.

In the present disclosure, “connected” includes not only direct connection with a connection terminal and/or a wiring conductor but also electrical connection via another circuit element. “Connected between A and B” means connection to both A and B between A and B and includes parallel connection (shunt connection) between a path between A and B and ground, in addition to direct connection to the path between A and B.

In the component arrangement in the present disclosure, a “plan view” means viewing an object that is orthographically projected on the x-y plane from the positive side of the z axis. “Overlapping of A with B in a plan view” means overlapping of the area of A orthographically projected on the x-y plane with the area of B orthographically projected on the x-y plane. “Arrangement of A between B and C” means passing of at least one line segment, among multiple line segments connecting an arbitrary point in B to an arbitrary point in C, through A. “Arrangement of A closer to C than B” means that the shortest distance between A and C is shorter than the shortest distance between B and C. The terms, such as parallel and vertical, indicating the relationship between elements, the terms, such as rectangles, indicating the shapes of the elements, and the numerical ranges do not represent only strict meanings but mean inclusion of a substantially equal range, for example, a difference on the order of few percent.

### Embodiment

### [1. Circuit Configuration of Power Amplifier Circuit 1 and Communication Device 7]

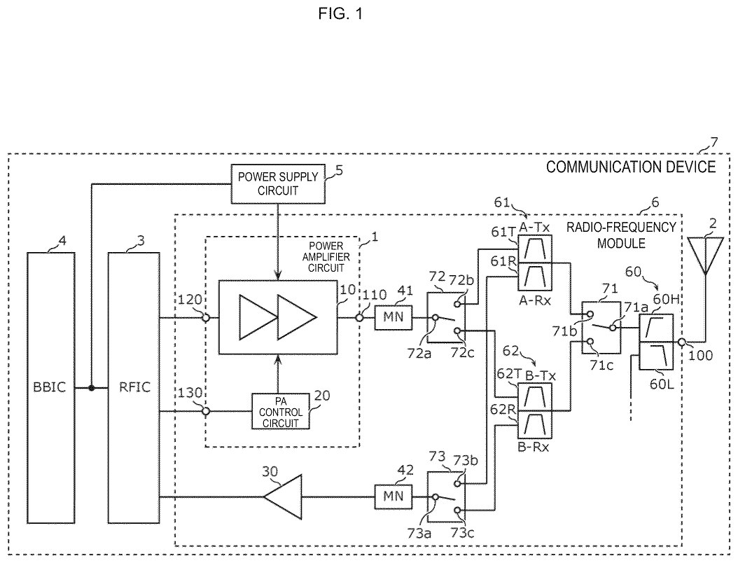

A circuit configuration of a power amplifier circuit 1 and a communication device 7 according to the present exemplary embodiment will now be described with reference to FIG. 1. FIG. 1 is a diagram illustrating the circuit configuration of the power amplifier circuit 1 and the communication device 7 according to the present exemplary embodiment.

### [1.1 Circuit Configuration of Communication Device 7]

First, the circuit configuration of the communication device 7 will be described. As illustrated in FIG. 1, the communication device 7 according to the present exemplary embodiment includes a radio-frequency module 6, an antenna 2, a radio-frequency integrated circuit (RFIC) 3, a baseband integrated circuit (BBIC) 4, and a power supply circuit 5.

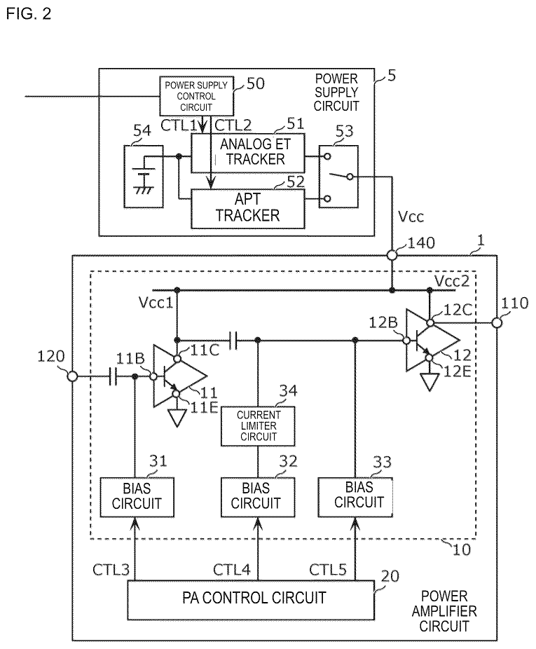

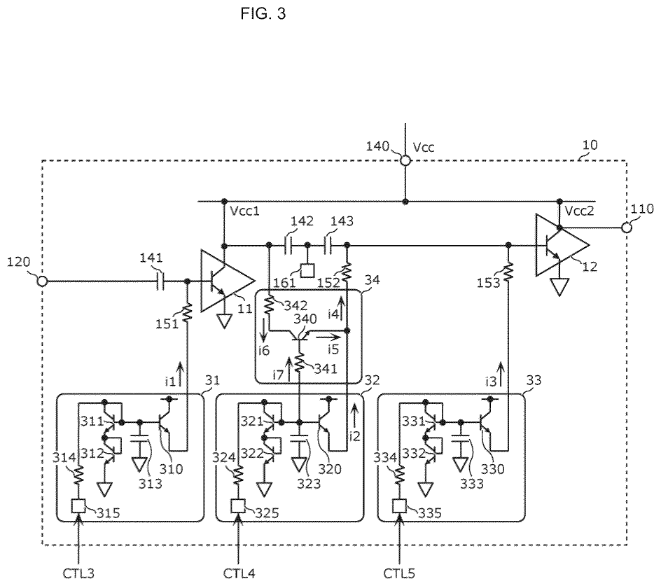

The radio-frequency module 6 includes the power amplifier circuit 1, a low noise amplifier 30, duplexers 61 and 62, a diplexer 60, matching circuits 41 and 42, and switches 71, 72, and 73. The radio-frequency module 6 transmits a radio-frequency signal between the antenna 2 and the RFIC 3. The configuration of the power amplifier circuit 1 will be described below with reference to FIG. 2 and FIG. 3.

The antenna 2 is connected to an antenna connection terminal 100 of the radio-frequency module 6. The radio-frequency signal output from the radio-frequency module 6 is transmitted through the antenna 2. In addition, the radio-frequency signal is externally received through the antenna 2 and the received radio-frequency signal is supplied to the radio-frequency module 6.

The RFIC 3 is one example of a signal processing circuit that processes the radio-frequency signal. Specifically, the RFIC 3 performs signal processing, such as down-conversion, to a radio-frequency reception signal input through an RF receive path of the radio-frequency module 6 and supplies a reception signal resulting from the signal processing to the BBIC 4. In addition, the RFIC 3 performs signal processing, such as up-conversion, to a transmission signal supplied from the BBIC 4 and supplies a radio-frequency transmission signal resulting from the signal processing to an RF transmit path of the radio-frequency module 6. Furthermore, the RFIC 3 includes a control unit that controls the radio-frequency module 6. Part or all of the functions of the RFIC 3 serving as the control unit may be installed outside the RFIC 3. For example, part or all of the functions of the RFIC 3 serving as the control unit may be installed in the BBIC 4 or the radio-frequency module 6.

The BBIC 4 is a baseband signal processing circuit that performs signal processing using an intermediate frequency band lower than the frequency band of the radio-frequency signal transmitted by the radio-frequency module 6. For example, an image signal for image display and/or an audio signal for talking with a speaker is used as the signal processed in the BBIC 4.

The power supply circuit 5 supplies power supply voltage Vcc to the power amplifier circuit 1. The configuration of the power supply circuit 5 will be described below with reference to FIG. 2.

The circuit configuration of the communication device 7 illustrated in FIG. 1 is only an example and is not limited to the one illustrated in FIG. 1. For example, the communication device 7 does not necessarily include the antenna 2 and/or the BBIC 4. In addition, for example, the communication device 7 may include multiple antennas.

### [1.2 Circuit Configuration of Radio-Frequency Module 6]

Next, the circuit configuration of the radio-frequency module 6 will be described.

The power amplifier circuit 1 has an input terminal 120 through which the radio-frequency transmission signal is input, an output terminal 110 thorough which the radio-frequency transmission signal (hereinafter referred to as the transmission signal) is output, and a control terminal 130 through which a control signal is received.

The switch 71 is connected between the antenna connection terminal 100 and the duplexers 61 and 62. The switch 71 has terminals 71a, 71b, and 71c. The terminal 71a is connected to the antenna connection terminal 100 via the diplexer 60. The terminal 71b is connected to the duplexer 61 and the terminal 71c is connected to the duplexer 62.

With this connection configuration, the switch 71 is capable of connecting the terminal 71a to either of the terminals 71b and 71c, for example, based on the control signal from the RFIC 3. In other words, the switch 71 is capable of switching the connection of the antenna connection terminal 100 between the duplexers 61 and 62. The switch 71 is composed of, for example, a single-pole double-throw (SPDT) switch circuit.

The switch 72 is connected between transmission filters 61T and 62T and the power amplifier circuit 1. The switch 72 has terminals 72a, 72b, and 72c. The terminal 72a is connected to the output terminal 110. The terminal 72b is connected to the transmission filter 61T and the terminal 72c is connected to the transmission filter 62T.

With this connection configuration, the switch 72 is capable of connecting the terminal 72a to either of the terminals 72b and 72c, for example, based on the control signal from the RFIC 3. In other words, the switch 72 is capable of switching the connection of the power amplifier circuit 1 between the transmission filters 61T and 62T. The switch 72 is composed of, for example, an SPDT switch circuit.

The switch 73 is connected between reception filters 61R and 62R and the low noise amplifier 30. The switch 73 has terminals 73a, 73b, and 73c. The terminal 73a is connected to the low noise amplifier 30. The terminal 73b is connected to the reception filter 61R and the terminal 73c is connected to the reception filter 62R.

With this connection configuration, the switch 73 is capable of connecting the terminal 73a to either of the terminals 73b and 73c, for example, based on the control signal from the RFIC 3. In other words, the switch 73 is capable of switching the connection of the low noise amplifier 30 between the reception filters 61R and 62R. The switch 73 is composed of, for example, an SPDT switch circuit.

The duplexer 61 has a passband including Band A. The duplexer 61 includes the transmission filter 61T and the reception filter 61R and enables frequency division duplex (FDD) in Band A.

The transmission filter 61T (A-Tx) is connected between the power amplifier circuit 1 and the antenna connection terminal 100. Specifically, one end of the transmission filter 61T is connected to the output terminal 110 via the switch 72. The other end of the transmission filter 61T is connected to the antenna connection terminal 100 via the switch 71 and the diplexer 60. The transmission filter 61T has a passband including an uplink operating band of Band A. Accordingly, the transmission filter 61T is capable of transmitting the transmission signal in Band A, among the transmission signals amplified by the power amplifier circuit 1.

The reception filter 61R (A-Rx) is connected between the low noise amplifier 30 and the antenna connection terminal 100. Specifically, one end of the reception filter 61R is connected to the antenna connection terminal 100 via the switch 71 and the diplexer 60. The other end of the reception filter 61R is connected to the low noise amplifier 30 via the switch 73. The reception filter 61R has a passband including a downlink operating band of Band A. Accordingly, the reception filter 61R is capable of transmitting the reception signal in Band A, among the reception signals received through the antenna 2.

The duplexer 62 has a passband including Band B. The duplexer 62 includes the transmission filter 62T and the reception filter 62R and enables the FDD in Band B.

The transmission filter 62T (B-Tx) is connected between the power amplifier circuit 1 and the antenna connection terminal 100. Specifically, one end of the transmission filter 62T is connected to the output terminal 110 via the switch 72. The other end of the transmission filter 62T is connected to the antenna connection terminal 100 via the switch 71 and the diplexer 60. The transmission filter 62T has a passband including an uplink operating band of Band B. Accordingly, the transmission filter 62T is capable of transmitting the transmission signal in Band B, among the transmission signals amplified by the power amplifier circuit 1.

The reception filter 62R (B-Rx) is connected between the low noise amplifier 30 and the antenna connection terminal 100. Specifically, one end of the reception filter 62R is connected to the antenna connection terminal 100 via the switch 71 and the diplexer 60. The other end of the reception filter 62R is connected to the low noise amplifier 30 via the switch 73. The reception filter 62R has a passband including a downlink operating band of Band B. Accordingly, the reception filter 62R is capable of transmitting the reception signal in Band B, among the reception signals received through the antenna 2.

Bands A and B are frequency bands for a communication system that is built using a radio access technology (RAT). Bands A and B are defined in advance by standardizing bodies or the likes (for example, 3rd Generation Partnership Project (3GPP) (registered trademark) and Institute of Electrical and Electronics Engineers (IEEE)). A 5th Generation New Radio (5GNR) system, a Long Term Evolution (LTE) system, a wireless local area network (WLAN) system, or the like is given as an example of the communication system.

The diplexer 60 includes a high pass filter 60H and a low pass filter 60L. One terminal of the high pass filter 60H and one terminal of the low pass filter 60L are connected to the antenna connection terminal 100. The other terminal of the high pass filter 60H is connected to the terminal 71a. The high pass filter 60H is a filter having a passband including a first frequency band group including Band A and Band B. The low pass filter 60L is a filter having a passband including a second frequency band group at a lower side of the first frequency band group. The diplexer 60 is not necessarily provided.

The matching circuit 41 is connected between the power amplifier circuit 1 and the switch 72 and performs impedance matching between output impedance of the power amplifier circuit 1 and input impedance of the transmission filters 61T and 62T. The matching circuit 41 is composed of, for example, at least one of an inductor and a capacitor.

The matching circuit 42 is connected between the low noise amplifier 30 and the switch 73 and performs impedance matching between input impedance of the low noise amplifier 30 and output impedance of the reception filters 61R and 62R. The matching circuit 42 is composed of, for example, at least one of an inductor and a capacitor.

The matching circuits 41 and 42 are not necessarily provided. A matching circuit may be arranged between the antenna connection terminal 100 and the duplexer 61 and a matching circuit may be arranged between the antenna connection terminal 100 and the duplexer 62.

The radio-frequency module 6 illustrated in FIG. 1 is only an example and is not limited to the one illustrated in FIG. 1. For example, the radio-frequency module 6 does not necessarily include the duplexer 62 and does not necessarily include the switches 71 to 73. In addition, the radio-frequency module 6 does not necessarily include the RF receive path and does not necessarily include the low noise amplifier 30 and the reception filter 61R. Furthermore, for example, the radio-frequency module 6 may include a filter and a power amplifier circuit corresponding to Band C different from Bands A and B.

### [1.3 Circuit Configuration of Power Amplifier Circuit 1 and Power Supply Circuit 5]

Next, a circuit configuration of the power amplifier circuit 1 and the power supply circuit 5 will be described.

FIG. 2 is a circuit block diagram of the power amplifier circuit 1 and the power supply circuit 5 according to the exemplary embodiment. As illustrated in FIG. 2, the power amplifier circuit 1 includes the input terminal 120, the output terminal 110, a power supply terminal 140, amplifier transistors 11 and 12, bias circuits 31, 32, and 33, a current limiter circuit 34, and a power amplifier (PA) control circuit 20. In the power amplifier circuit 1, the amplifier transistor 11 and 12, the bias circuits 31, 32, and 33, and the current limiter circuit 34 compose a power amplifier 10.

The power supply terminal 140 is a terminal for receiving the power supply voltage Vcc, which is varied in accordance with an envelope of a radio-frequency input signal to be input into the power amplifier circuit 1, from the power supply circuit 5.

The amplifier transistor 11 is one example of a second amplifier transistor and is a bipolar transistor having a base terminal 11B, a collector terminal 11C, and an emitter terminal 11E. The amplifier transistor 11 is cascade-connected to the amplifier transistor 12 and is arranged at a previous stage (a drive stage) of the amplifier transistor 12. The base terminal 11B is connected to the input terminal 120, the collector terminal 11C is connected to the power supply terminal 140, and the emitter terminal 11E is grounded. At least one of an inductor and a capacitor may be connected between the base terminal 11B and the input terminal 120, at least one of an inductor and a capacitor may be connected between the collector terminal 11C and the power supply terminal 140, and at least one of an inductor and a capacitor may be connected between the emitter terminal 11E and the ground.

With the above configuration, the amplifier transistor 11 performs power amplification to the radio-frequency input signal input through the input terminal 120 and outputs the radio-frequency signal resulting from the power amplification from the collector terminal 11C.

The amplifier transistor 12 is one example of a first amplifier transistor and is a bipolar transistor having a base terminal 12B (a first control terminal), a collector terminal 12C (a first terminal), and an emitter terminal 12E (a second terminal). The amplifier transistor 12 is arranged at a subsequent stage (a power stage) of the amplifier transistor 11. The base terminal 12B is connected to the collector terminal 11C, the collector terminal 12C is connected to the power supply terminal 140 and the output terminal 110, and the emitter terminal 12E is grounded. At least one of an inductor and a capacitor may be connected between the base terminal 12B and the collector terminal 11C, at least one of an inductor and a capacitor may be connected between the collector terminal 12C, and the power supply terminal 140 and the output terminal 110, and at least one of an inductor and a capacitor may be connected between the emitter terminal 12E and the ground.

With the above configuration, the amplifier transistor 12 performs the power amplification to the radio-frequency signal output from the collector terminal 11C of the amplifier transistor 11 and outputs the radio-frequency signal resulting from the power amplification from the collector terminal 12C.

The amplifier transistors 11 and 12 may have a collector grounded circuit configuration or the like, instead of the emitter grounded circuit configuration. In addition, the amplifier transistors 11 and 12 are not limited to the bipolar transistors and may be, for example, metal-oxide-semiconductor field-effect-transistors (MOSFETs) each having a gate terminal, a drain terminal, and a source terminal.

The bias circuit 31 is a circuit that supplies direct-current bias current to the base terminal 11B of the amplifier transistor 11.

The bias circuit 32 is one example of a first bias circuit and is a circuit that supplies the direct-current bias current (first direct-current bias current) to the base terminal 12B of the amplifier transistor 12.

The bias circuit 33 is one example of a second bias circuit and is a circuit that supplies the direct-current bias current (second direct-current bias current) to the base terminal 12B of the amplifier transistor 12.

The current limiter circuit 34 is one example of a modulation circuit. The current limiter circuit 34 is a circuit that is connected to the bias circuit 32 and the amplifier transistor 12 and that varies (modulates) the magnitude of the first direct-current bias current in accordance with the magnitude of the power supply voltage Vcc.

The PA control circuit 20 is one example of a control circuit and switches between the supply of the first direct-current bias current to the amplifier transistor 12 and the supply of the second direct-current bias current to the amplifier transistor 12 in accordance with a channel bandwidth of the radio-frequency input signal input into the power amplifier circuit 1.

The power amplifier 10 may include three or more amplifier transistors that include the amplifier transistors 11 and 12 and that are cascade-connected to each other. In this case, the amplifier transistor 12 is a last-stage (power stage) amplifier transistor.

The power supply circuit 5 includes a power supply 54, an analog ET tracker 51, an APT tracker 52, a switch 53, and a power supply control circuit 50.

The APT tracker 52 generates the power supply voltage of multiple discrete voltage levels based on the voltage of the power supply 54. More specifically, the APT tracker 52 includes, for example, multiple voltage holding circuits (or voltage holding elements) that hold different voltage levels. The APT tracker 52 selects one voltage holding circuit from the multiple voltage holding circuits to output the power supply voltage of one voltage level from the selected one voltage holding circuit. The APT tracker 52 does not necessarily prepare the multiple voltage levels in advance. The APT tracker 52 does not necessarily select the voltage level with the switch to output the power supply voltage of the selected voltage level. For example, the APT tracker 52 may generate the power supply voltage of the voltage level selected from the multiple discrete voltage levels, as needed, to output the generated power supply voltage.

The analog ET tracker 51 generates the power supply voltage of a continuous voltage level based on the voltage of the power supply 54. More specifically, the analog ET tracker 51 includes a voltage holding circuit the voltage level of which is varied. The analog ET tracker 51 outputs the power supply voltage of the varied voltage level from the voltage holding circuit.

The switch 53 has a common terminal connected to the power supply terminal 140, a first selection terminal connected to the analog ET tracker 51, and a second selection terminal connected to the APT tracker 52. The switch 53 switches between the connection between the analog ET tracker 51 and the power supply terminal 140 and the connection between the APT tracker 52 and the power supply terminal 140.

The power supply control circuit 50 continuously varies the voltage level of the power supply voltage Vcc generated in the analog ET tracker 51 based on an envelope signal of the radio-frequency input signal supplied from the BBIC 4 and selects the voltage level of the power supply voltage Vcc used in the power amplifier circuit 1 from the multiple discrete voltage levels generated in the APT tracker 52 in accordance with average output power of the radio-frequency signal. In addition, the power supply control circuit 50 switches the connection of the switch 53 based on the frequency and the channel bandwidth of the radio-frequency signal input into the power amplifier circuit 1.

The power supply control circuit 50 may control the voltage level of the analog ET tracker 51 so that the power amplitude of the radio-frequency input signal is a linear function of the voltage.

With the above configuration, it is sufficient to monitor the power supply voltage Vcc, which has linear relationship (the linear function) with the power level, instead of monitoring of the power level of the radio-frequency signal, to operate the current limiter circuit 34. Accordingly, it is possible to simplify the circuit configuration of the current limiter circuit 34.

The envelope signal is a signal indicating the envelope of the radio-frequency input signal (modulated signal). The envelope value is represented by, for example, √(i²+Q²). Here, (I, Q) represents a constellation point. The constellation point is a point representing the signal modulated through digital modulation on a constellation diagram. (I, Q) is determined by the BBIC 4 based on, for example, transmission information.

The power supply control circuit 50 may be included in the RFIC 3, instead of the power supply circuit 5.

In the following description, varying the power supply voltage to the multiple discrete voltage levels in units of one frame based on the average output power of the radio-frequency signal is referred to as average power tracking (APT) and a mode in which the APT is applied to the power supply voltage is referred to as an APT mode. Tracking of the envelope of the radio-frequency signal using the continuous voltage level is referred as analog envelope tracking (analog ET) and a mode in which the analog ET is applied to the power supply voltage is referred to as an analog ET mode.

The frame represents a unit composing the radio-frequency signal (the modulated signal). For example, in 5GNR and LTE, the frame includes ten subframes, each subframe includes multiple slots, and each slot is composed of multiple symbols. The subframe has a length of 1 ms and the frame has a length of 10 ms.

Next, an example of the circuit configuration of the power amplifier 10 (the bias circuits 31 to 33 and the current limiter circuit 34) will be described.

FIG. 3 is a diagram illustrating a circuit configuration of the power amplifier 10 according to the exemplary embodiment. The power amplifier 10 includes the amplifier transistors 11 and 12, the bias circuits 31, 32, and 33, the current limiter circuit 34, capacitors 141, 142, and 143, resistive elements 151, 152, and 153, and an impedance matching circuit 161.

The bias circuit 31 includes a constant current amplifier transistor 310, transistors 311 and 312 diode-connected to each other, a capacitor 313, a resistive element 314, and a constant current source 315.

The constant current amplifier transistor 310 has a collector terminal, an emitter terminal, and a base terminal and supplies direct-current bias current it from the emitter terminal to the base terminal 11B of the amplifier transistor 11. With this configuration, constant current output from the constant current source 315 is supplied to the base terminal of the constant current amplifier transistor 310, the constant current is amplified to generate the direct-current bias current i1, and the direct-current bias current it is applied from the emitter terminal of the constant current amplifier transistor 310 to the base terminal 11B of the amplifier transistor 11 via the resistive element 151.

The bias circuit 32 is one example of the first bias circuit and supplies direct-current bias current i2 (the first direct-current bias current) to the base terminal 12B of the amplifier transistor 12. More specifically, the bias circuit 32 includes a constant current amplifier transistor 320, transistors 321 and 322 diode-connected to each other, a capacitor 323, a resistive element 324, and a constant current source 325.

The constant current amplifier transistor 320 is one example of a first transistor. The constant current amplifier transistor 320 is a constant current amplifier transistor that has a collector terminal (a third terminal), an emitter terminal (a fourth terminal), and a base terminal (a second control terminal) and that supplies the direct-current bias current i2 from the emitter terminal to the base terminal 12B (the first control terminal) of the amplifier transistor 12. With this configuration, the constant current output from the constant current source 325 is supplied to the base terminal of the constant current amplifier transistor 320, the constant current is amplified to generate the direct-current bias current i2, and the direct-current bias current i2 is applied from the emitter terminal of the constant current amplifier transistor 320 to the base terminal 12B of the amplifier transistor 12 via the resistive element 152.

The bias circuit 33 is one example of the second bias circuit. The bias circuit 33 supplies direct-current bias current i3 (the second direct-current bias current) to the base terminal 12B of the amplifier transistor 12. More specifically, the bias circuit 33 includes a constant current amplifier transistor 330, transistors 331 and 332 diode-connected to each other, a capacitor 333, a resistive element 334, and a constant current source 335.

The constant current amplifier transistor 330 is one example of a third transistor. The constant current amplifier transistor 330 is a constant current amplifier transistor that has a collector terminal (a seventh terminal), an emitter terminal (an eighth terminal), and a base terminal (a fourth control terminal) and that supplies the direct-current bias current i3 from the emitter terminal to the base terminal 12B (the first control terminal) of the amplifier transistor 12. With this configuration, the constant current output from the constant current source 335 is supplied to the base terminal of the constant current amplifier transistor 330, the constant current is amplified to generate the direct-current bias current i3, and the direct-current bias current i3 is applied from the emitter terminal of the constant current amplifier transistor 330 to the base terminal 12B of the amplifier transistor 12 via the resistive element 153.

The current limiter circuit 34 is one example of the modulation circuit. The current limiter circuit 34 is a circuit that limits the direct-current bias current i2 output from the bias circuit 32. More specifically, the current limiter circuit 34 includes a current limiting transistor 340 and resistive elements 341 and 342.

The current limiting transistor 340 is one example of a second transistor and has a collector terminal (a fifth terminal), an emitter terminal (a sixth terminal), and a base terminal (a third control terminal). The emitter terminal (the sixth terminal) is connected to the emitter terminal (the fourth terminal) of the constant current amplifier transistor 320.

The resistive element 342 is one example of a first resistive element. One end of the resistive element 342 is connected to the collector terminal (the fifth terminal) of the current limiting transistor 340 and the other end thereof is connected to the power supply terminal 140.

The resistive element 341 is one example of a second resistive element. One end of the resistive element 341 is connected to the base terminal (the third control terminal) of the current limiting transistor 340 and the other end thereof is connected to the base terminal (the second control terminal) of the constant current amplifier transistor 320.

With the above connection configuration, if collector-side voltage Vcc1 to be applied to the amplifier transistor 11 is lower than reference voltage, the current limiter circuit 34 increases direct-current limiting current (−i6) as the difference in potential between the collector-side voltage Vcc1 and the reference voltage is increased. The direct-current limiting current (−i6) is the direct current that flows from the base terminal (the second control terminal) of the constant current amplifier transistor 320 to the collector terminal (the fifth terminal) of the current limiting transistor 340 via the base terminal (the third control terminal) of the current limiting transistor 340. The reference voltage is, for example, the maximum power supply voltage Vcc that is set when the radio-frequency input signal input into the power amplifier circuit 1 has the maximum power amplitude.

The capacitors 141, 142, and 143 are DC cutting capacitance elements that remove the direct-current component of the radio-frequency signal.

The impedance matching circuit 161 is a circuit that matches the output impedance of the amplifier transistor 11 with the input impedance of the amplifier transistor 12.

In the power amplifier 10 according to the present exemplary embodiment, the resistive elements 151 to 153, the capacitors 141 to 143, and the impedance matching circuit 161 are appropriately removed or replaced with other circuit elements depending on required specifications or the likes of the power amplifier 10.

The constant current source 315 in the bias circuit 31 switches the presence of generation of the constant current based on a control signal CTL3 from the PA control circuit 20. The constant current source 325 in the bias circuit 32 switches the presence of generation of the constant current based on a control signal CTL4 from the PA control circuit 20. The constant current source 335 in the bias circuit 33 switches the presence of generation of the constant current based on a control signal CTL5 from the PA control circuit 20.

The current limiter circuit 34 and the bias circuit 33 may be connected on a path between an output terminal of the amplifier transistor 11 and an input terminal of the amplifier transistor 12 in this order from the side closer to the amplifier transistor 11.

With the above configuration, since the current limiter circuit 34 is connected so as to be closer to Vcc1, among the collector-side voltage Vcc1 and collector-side voltage Vcc2, the voltage value of the collector-side voltage (the power supply voltage Vcc) with small radio-frequency noise is capable of being monitored. As a result, it is possible to accurately generate the direct-current limiting current (−i6).

### [1.4 Application to Analog ET Mode and APT Mode]

Exemplary effects and advantages when the analog ET mode and the APT mode are applied to the power amplifier circuit 1 according to the present exemplary embodiment will now be described.

When the communication device 7 according to the present exemplary embodiment is used as user equipment (UE) in a cellular network, the communication device 7 controls output power based on a transfer power control command (TPC_cmd) transmitted from a base station to the UE (the Third Generation Partnership Project (3GPP) (registered trademark): Inner loop power control). In the 4th Generation (4G) and the 5th Generation (5G), the required accuracy of the output power of the UE is high. For example, when the transfer power control command in a mode of TPC_cmd(+1) is transmitted from the base station, it is necessary for the UE to adjust the output power within a range from +0.5 dB to +1.5 dB with respect to the instruction value. For example, when the transfer power control command in a mode of TPC_cmd(0) is transmitted from the base station, it is necessary for the UE to adjust the output power within a range from −0.5 dB to +0.5 dB with respect to the instruction value. For example, when the transfer power control command in a mode of TPC_cmd(−1) is transmitted from the base station, it is necessary for the UE to adjust the output power within a range from −1.5 dB to −0.5 dB with respect to the instruction value.

However, in the power amplifier circuit having high gain deviation caused by variation in the power supply voltage Vcc, particularly in a high-gain region, the power of the radio-frequency signal output from the power amplifier circuit may be without the output power range corresponding to the transfer power control command. In other words, it is assumed that output power specifications (power range) corresponding to the transfer power control command are not met to reduce the quality of the radio-frequency output signal.

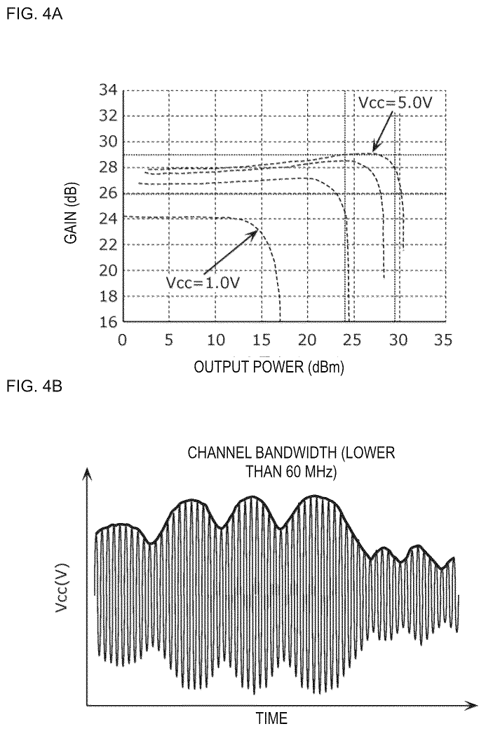

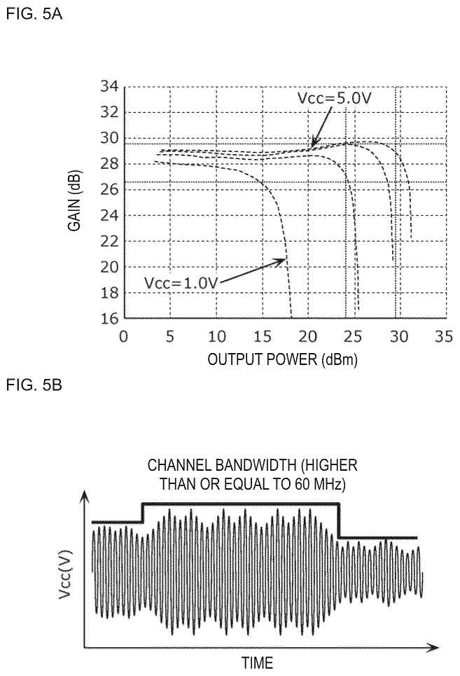

FIG. 4A is a graph indicating the relationship between the output power and the gain of the power amplifier circuit 1 in the analog ET mode. FIG. 4B is a graph indicating one example of transition of the power supply voltage Vcc in the analog ET mode. FIG. 5A is a graph indicating the relationship between the output power and the gain of the power amplifier circuit 1 in the APT mode. FIG. 5B is a graph indicating one example of transition of the power supply voltage Vcc in the APT mode.

Referring to FIG. 4A and FIG. 5A, the horizontal axis represents the output power from the power amplifier circuit 1 and the vertical axis represents the gain of the power amplifier circuit 1.

Referring to FIG. 4B and FIG. 5B, the horizontal axis represents time and the vertical axis represents voltage. A bold line represents the power supply voltage Vcc and a thin line (wave shape) represents the modulated signal.

In the analog ET mode, the power supply voltage Vcc is continuously varied to track the envelope of the modulated signal, as illustrated in FIG. 4B. In the analog ET mode, the power supply voltage Vcc is determined based on the envelope signal (√(i²+Q²)). The gain of the power amplifier circuit 1 is increased as the power supply voltage Vcc is increased, as indicated in FIG. 4A. At this time, in the analog ET mode, the direct-current bias current to be supplied to the amplifier transistor 12 is made varied in accordance with the magnitude of the power supply voltage Vcc with the emphasis on power-added efficiency and linearity of the power amplifier circuit 1. Specifically, in the analog ET mode, the direct-current bias current to be supplied to the amplifier transistor 12 is increased as the power supply voltage Vcc is increased. In the analog ET mode, controlling the direct-current bias current in accordance with the power supply voltage Vcc in the above manner enables the gain to be stabilized with respect to the variation in the output power. In other words, since the gain deviation is reduced in the analog ET mode, it is possible to meet the output power specifications (the power range) when the output power is controlled in accordance with the transfer power control command from the base station to suppress reduction in quality of the transmission signal.

However, in the analog ET, the power supply voltage Vcc is capable of tracking the variation in the envelope of the modulated signal when the channel bandwidth is relatively low (for example, lower than 60 MHz) as in FIG. 4B while the power supply voltage Vcc is not capable of tracking the variation in the envelope of the modulated signal when the channel bandwidth is relatively high (higher than or equal to 60 MHz). In other words, when the channel bandwidth is relatively high, the variation in amplitude of the power supply voltage Vcc is delayed from the variation in the envelope of the modulated signal.

In contrast, when the channel bandwidth is relatively high (for example, higher than or equal to 60 MHz) as in FIG. 5B, the application of the APT mode improves the degree of tracking of the power supply voltage Vcc to the modulated signal.

Gain characteristics when the APT mode is applied and the direct-current bias current is not varied in accordance with the variation in the power supply voltage Vcc are indicated in FIG. 5A. As indicated in FIG. 5A, when the APT mode is applied, the gain deviation is capable of being reduced with respect to the variation in the power supply voltage Vcc when the direct-current bias current is not varied with the power supply voltage Vcc. Accordingly, it is possible to meet the output power specifications (the power range) when the output power is controlled in accordance with the transfer power control command from the base station to suppress the reduction in quality of the transmission signal.

As described above, differentiating the control of the direct-current bias current to be supplied to the amplifier transistor 12 between the analog ET mode and the APT mode enables reduction in amplification characteristics of the power amplifier circuit 1 to be suppressed.

### [1.5 Bias Control in Analog ET Mode and APT Mode]

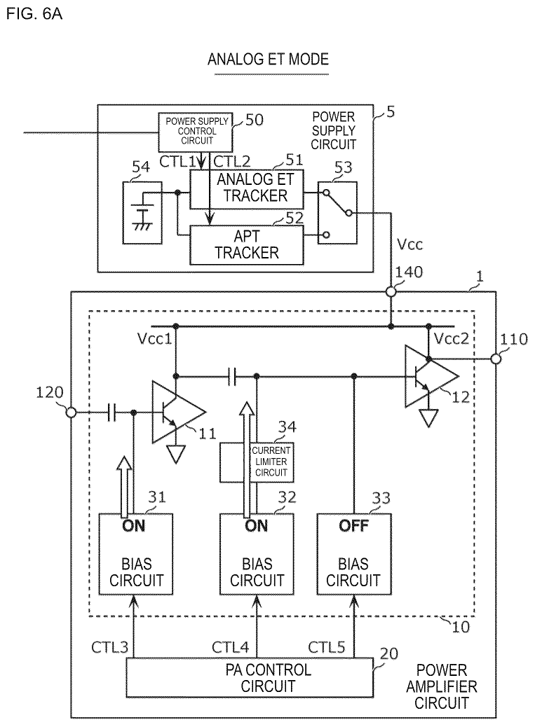

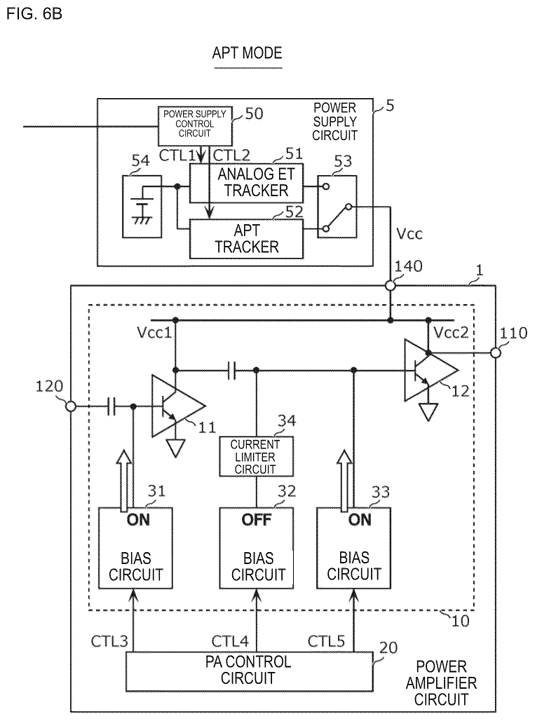

FIG. 6A is a diagram illustrating the circuit state in the analog ET mode of the power amplifier circuit 1 and the power supply circuit 5 according to the exemplary embodiment. As illustrated in FIG. 6A, in the analog ET mode, the direct-current bias current is supplied from the bias circuit 32 and the current limiter circuit 34 to the amplifier transistor 12 and the direct-current bias current is not supplied from the bias circuit 33 to the amplifier transistor 12. The direct-current bias current is supplied from the bias circuit 31 to the amplifier transistor 11.

Specifically, the power supply control circuit 50 connects the common terminal of the switch 53 to the first selection terminal thereof, and the PA control circuit 20 causes the bias circuit 32 and the current limiter circuit 34 to supply the direct-current bias current to the base terminal 12B of the amplifier transistor 12 with the control signal CTL4 and causes the bias circuit 33 not to supply the direct-current bias current to the base terminal 12B of the amplifier transistor 12 with the control signal CTL5. In addition, the PA control circuit 20 causes the bias circuit 31 to supply the direct-current bias current to the base terminal 11B of the amplifier transistor 11 with the control signal CTL3.

With this circuit state, in the analog ET mode, the direct-current bias current to be supplied to the amplifier transistor 12 is increased as the power supply voltage Vcc is increased. Accordingly, in the analog ET mode, since the gain deviation is capable of being reduced when the output power is varied while ensuring the power-added efficiency and the linearity, it is possible to meet the output power specifications (the power range) when the output power is controlled in accordance with the transfer power control command from the base station to suppress the reduction in quality of the transmission signal.

FIG. 6B is a diagram illustrating the circuit state in the APT mode of the power amplifier circuit 1 and the power supply circuit 5 according to the exemplary embodiment. As illustrated in FIG. 6B, in the APT mode, the direct-current bias current is supplied from the bias circuit 33 to the amplifier transistor 12 and the direct-current bias current is not supplied from the bias circuit 32 and the current limiter circuit 34 to the amplifier transistor 12. The direct-current bias current is supplied from the bias circuit 31 to the amplifier transistor 11.

Specifically, the power supply control circuit 50 connects the common terminal of the switch 53 to the second selection terminal thereof, and the PA control circuit 20 causes the bias circuit 33 to supply the direct-current bias current to the base terminal 12B of the amplifier transistor 12 with the control signal CTL5 and causes the bias circuit 32 and the current limiter circuit 34 not to supply the direct-current bias current to the base terminal 12B of the amplifier transistor 12 with the control signal CTL4. In addition, the PA control circuit 20 causes the bias circuit 31 to supply the direct-current bias current to the base terminal 11B of the amplifier transistor 11 with the control signal CTL3.

With this circuit state, in the APT mode, the direct-current bias current to be supplied to the amplifier transistor 12 is not varied with the variation in the power supply voltage Vcc. Accordingly, in the APT mode, since the gain deviation when the power supply voltage Vcc is varied is capable of being reduced, it is possible to meet the output power specifications (the power range) when the output power is controlled in accordance with the transfer power control command from the base station to suppress the reduction in quality of the transmission signal.

In the power amplifier circuit 1 according to the present exemplary embodiment, the PA control circuit 20 may cause the bias circuit 32 and the current limiter circuit 34 to supply the direct-current bias current to the base terminal 12B when a first radio-frequency input signal of a first channel bandwidth is input into the amplifier transistor 12 and may cause the bias circuit 33 to supply the direct-current bias current to the base terminal 12B when a second radio-frequency input signal of a second channel bandwidth wider than the first channel bandwidth is input into the amplifier transistor 12.

In this case, the gain deviation when the output power is varied while ensuring the power-added efficiency and the linearity is capable of being reduced even in the analog ET mode when the first radio-frequency input signal is input into the amplifier transistor 12. Accordingly, it is possible to meet the output power specifications (the power range) when the output power is controlled in accordance with the transfer power control command from the base station to suppress the reduction in quality of the transmission signal. In addition, the gain deviation when the output power is varied is capable of being reduced even in the APT mode when the second radio-frequency input signal is input into the amplifier transistor 12. Accordingly, it is possible to meet the output power specifications (the power range) when the output power is controlled in accordance with the transfer power control command from the base station to suppress the reduction in quality of the transmission signal.

The supply mode of the power supply voltage when the first radio-frequency input signal is input into the amplifier transistor 12 may be either of the analog ET mode and the APT mode or may be an ET mode different from the analog ET mode. The supply mode of the power supply voltage when the second radio-frequency input signal is input into the amplifier transistor 12 may be either of the analog ET mode and the APT mode or may be an ET mode different from the analog ET mode.

In the power amplifier circuit 1 according to the present exemplary embodiment, the PA control circuit 20 may switch between the supply of the first direct-current bias current to the base terminal 12B and the supply of the second direct-current bias current to the base terminal 12B in accordance with the channel bandwidth of the radio-frequency signal input into the amplifier transistor.

Specifically, the PA control circuit 20 may cause the bias circuit 32 and the current limiter circuit 34 to supply the direct-current bias current to the base terminal 12B when the channel bandwidth of the radio-frequency signal input into the amplifier transistor is lower than a predetermined bandwidth and may cause the bias circuit 33 to supply the direct-current bias current to the base terminal 12B when the channel bandwidth of the radio-frequency signal input into the amplifier transistor is higher than or equal to the predetermined bandwidth. Here, the predetermined bandwidth is, for example, 60 MHz.

In this case, since the gain deviation when the output power is varied while ensuring the power-added efficiency and the linearity is capable of being reduced when the channel bandwidth is relatively low, it is possible to meet the output power specifications (the power range) when the output power is controlled in accordance with the transfer power control command from the base station to suppress the reduction in quality of the transmission signal. In addition, since the gain deviation when the power supply voltage Vcc and the output power are varied is capable of being reduced when the channel bandwidth is relatively high, it is possible to meet the output power specifications (the power range) when the output power is controlled in accordance with the transfer power control command from the base station to suppress the reduction in quality of the transmission signal.

In the power amplifier circuit 1 according to the present exemplary embodiment, the PA control circuit 20 may cause the bias circuit 32 and the current limiter circuit 34 to supply the direct-current bias current to the base terminal 12B when a third radio-frequency input signal is input into the amplifier transistor 12 and may cause the bias circuit 33 to supply the direct-current bias current to the base terminal 12B when a fourth radio-frequency input signal of a frequency band higher than that of the third radio-frequency input signal is input into the amplifier transistor 12.

In this case, the gain deviation when the output power is varied while ensuring the power-added efficiency and the linearity is capable of being reduced even in the analog ET mode when the third radio-frequency input signal is input into the amplifier transistor 12. Accordingly, it is possible to meet the output power specifications (the power range) when the output power is controlled in accordance with the transfer power control command from the base station to suppress the reduction in quality of the transmission signal. In addition, the gain deviation when the output power is varied is capable of being reduced even in the APT mode when the fourth radio-frequency input signal is input into the amplifier transistor 12. Accordingly, it is possible to meet the output power specifications (the power range) when the output power is controlled in accordance with the transfer power control command from the base station to suppress the reduction in quality of the transmission signal.

### [1.6 Configuration and Bias Control of Power Amplifier 15 According to Modification]

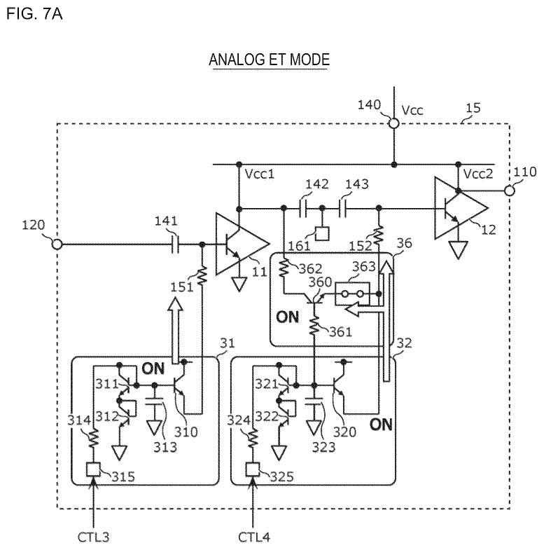

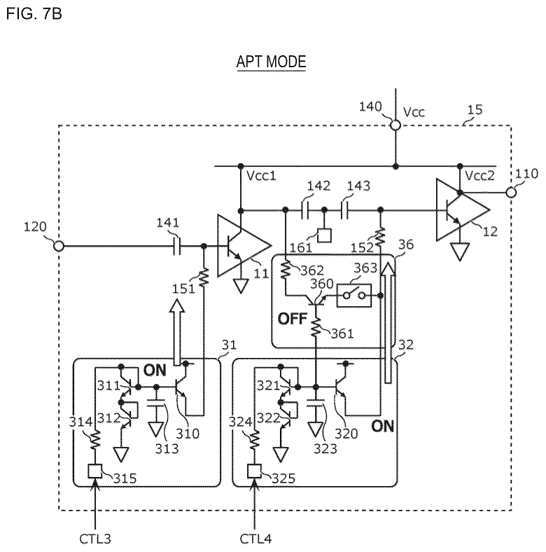

FIG. 7A is a diagram illustrating the circuit state in the analog ET mode of a power amplifier 15 according to a modification of the exemplary embodiment. FIG. 7B is a diagram illustrating the circuit state in the APT mode of the power amplifier 15 according to the modification of the exemplary embodiment.

As illustrated in FIG. 7A and FIG. 7B, the power amplifier 15 according to the present modification includes the amplifier transistors 11 and 12, the bias circuits 31 and 32, a current limiter circuit 36, the capacitors 141, 142, and 143, the resistive elements 151 and 152, and the impedance matching circuit 161. The power amplifier 15 according to the present modification differs from the power amplifier 10 according to the exemplary embodiment in that the power amplifier 15 does not include the bias circuit 33 and in the configuration of the current limiter circuit 36. A description of the same components as those in the power amplifier 10 according to the exemplary embodiment in the power amplifier 15 according to the present modification is omitted herein and the description focuses on components different from those in the power amplifier 10 according to the exemplary embodiment.

The bias circuit 32 is one example of the first bias circuit and supplies the direct-current bias current (the first direct-current bias current) to the base terminal 12B of the amplifier transistor 12.

The current limiter circuit 36 is one example of the modulation circuit and is a circuit that limits the direct-current bias current output from the bias circuit 32. More specifically, the current limiter circuit 36 includes a current limiting transistor 360, resistive elements 361 and 362, and a switch 363.

The current limiting transistor 360 is one example of the second transistor and has a collector terminal (the fifth terminal), an emitter terminal (the sixth terminal), and a base terminal (the third control terminal). The emitter terminal (the sixth terminal) is connected to one end (the seventh terminal) of the switch 363.

The switch 363 is one example of a first switch and has one end (the seventh terminal) and the other end (the eighth terminal). The other end (the eighth terminal) of the switch 363 is connected to the emitter terminal (the fourth terminal) of the constant current amplifier transistor 320. The switch 363 is composed of, for example, a single-pole single-throw (SPST) switch circuit.

The resistive element 362 is one example of the first resistive element. One end of the resistive element 362 is connected to the collector terminal (the fifth terminal) of the current limiting transistor 360 and the other end thereof is connected to the power supply terminal 140.

The resistive element 361 is one example of the second resistive element. One end of the resistive element 361 is connected to the base terminal (the third control terminal) of the current limiting transistor 360 and the other end thereof is connected to the base terminal (the second control terminal) of the constant current amplifier transistor 320.

With the above connection configuration, if the collector-side voltage Vcc1 to be applied to the amplifier transistor 11 is lower than the reference voltage when the switch 363 is in a conductive state, the current limiter circuit 36 increases the direct-current limiting current as the difference in potential between the collector-side voltage Vcc1 and the reference voltage is increased. The direct-current limiting current is the direct current that flows from the base terminal (the second control terminal) of the constant current amplifier transistor 320 to the collector terminal (the fifth terminal) of the current limiting transistor 360 via the base terminal (the third control terminal) of the current limiting transistor 360. In contrast, when the switch 363 is in a non-conductive state, the current limiter circuit 36 does not generate the direct-current limiting current.

Next, the bias control in the analog ET mode and the APT mode in the power amplifier circuit including the power amplifier 15 according to the modification will be described. The power amplifier circuit according to the present modification includes the power amplifier 15 and the PA control circuit 20.

As illustrated in FIG. 7A, in the analog ET mode, the direct-current bias current is supplied from the bias circuit 32 and the current limiter circuit 36 to the amplifier transistor 12. The direct-current bias current is supplied from the bias circuit 31 to the amplifier transistor 11.

Specifically, the PA control circuit 20 sets the switch 363 to the conductive state to cause the bias circuit 32 and the current limiter circuit 36 to supply the direct-current bias current to the base terminal 12B of the amplifier transistor 12 with the control signal CTL4. In addition, the PA control circuit 20 causes the bias circuit 31 to supply the direct-current bias current to the base terminal 11B of the amplifier transistor 11 with the control signal CTL3.

With this circuit state, in the analog ET mode, the direct-current bias current to be supplied to the amplifier transistor 12 is increased as the power supply voltage Vcc is increased. Accordingly, in the analog ET mode, since the gain deviation is small, it is possible to meet the output power specifications (the power range) when the output power is controlled in accordance with the transfer power control command from the base station to suppress the reduction in quality of the transmission signal.

In contrast, as illustrated in FIG. 7B, in the APT mode, the direct-current bias current is supplied from the bias circuit 32 to the amplifier transistor 12. The direct-current bias current is supplied from the bias circuit 31 to the amplifier transistor 11.

Specifically, the PA control circuit 20 sets the switch 363 to the non-conductive state to cause only the bias circuit 32 to supply the direct-current bias current to the base terminal 12B of the amplifier transistor 12 with the control signal CTL4. In addition, the PA control circuit 20 causes the bias circuit 31 to supply the direct-current bias current to the base terminal 11B of the amplifier transistor 11 with the control signal CTL3.

With this circuit state, in the APT mode, the direct-current bias current to be supplied to the amplifier transistor 12 is not varied with the variation in the power supply voltage Vcc. Accordingly, in the APT mode, since the gain deviation when the power supply voltage Vcc is varied is capable of being reduced, it is possible to meet the output power specifications (the power range) when the output power is controlled in accordance with the transfer power control command from the base station to suppress the reduction in quality of the transmission signal.

In the power amplifier circuit according to the present modification, the PA control circuit 20 may set the switch 363 to the conductive state (connection of one end of the switch 363 to the other end thereof) when the first radio-frequency input signal of the first channel bandwidth is input into the amplifier transistor 12 and may set the switch 363 to the non-conductive state (non-connection of one end of the switch 363 to the other end thereof) when the second radio-frequency input signal of the second channel bandwidth wider than the first channel bandwidth is input into the amplifier transistor 12.

In this case, the gain deviation when the output power is varied while ensuring the power-added efficiency and the linearity is capable of being reduced even in the analog ET mode when the first radio-frequency input signal is input into the amplifier transistor 12. Accordingly, it is possible to meet the output power specifications (the power range) when the output power is controlled in accordance with the transfer power control command from the base station to suppress the reduction in quality of the transmission signal output from the power amplifier circuit according to the present modification. In addition, the gain deviation when the output power is varied is capable of being reduced even in the APT mode when the second radio-frequency input signal is input into the amplifier transistor 12. Accordingly, it is possible to meet the output power specifications (the power range) when the output power is controlled in accordance with the transfer power control command from the base station to suppress the reduction in quality of the transmission signal output from the power amplifier circuit according to the present modification.

The supply mode of the power supply voltage when the first radio-frequency input signal is input into the amplifier transistor 12 may be either of the analog ET mode and the APT mode or may be an ET mode different from the analog ET mode. The supply mode of the power supply voltage when the second radio-frequency input signal is input into the amplifier transistor 12 may be either of the analog ET mode and the APT mode or may be an ET mode different from the analog ET mode.

In the power amplifier circuit according to the present modification, the PA control circuit 20 may switch between the supply of the first direct-current bias current to the base terminal 12B and the supply of the second direct-current bias current to the base terminal 12B in accordance with the channel bandwidth of the radio-frequency signal input into the amplifier transistor.

Specifically, the PA control circuit 20 may set the switch 363 to the conductive state (connection of one end of the switch 363 to the other end thereof) when the channel bandwidth of the radio-frequency signal input into the amplifier transistor is lower than a predetermined bandwidth and may set the switch 363 to the non-conductive state (non-connection of one end of the switch 363 to the other end thereof) when the channel bandwidth of the radio-frequency signal input into the amplifier transistor is higher than or equal to the predetermined bandwidth. Here, the predetermined bandwidth is, for example, 60 MHz.

In this case, since the gain deviation when the output power is varied while ensuring the power-added efficiency and the linearity is capable of being reduced when the channel bandwidth is relatively low, it is possible to meet the output power specifications (the power range) when the output power is controlled in accordance with the transfer power control command from the base station to suppress the reduction in quality of the transmission signal output from the power amplifier circuit according to the present modification. In addition, since the gain deviation when the power supply voltage Vcc and the output power are varied is capable of being reduced when the channel bandwidth is relatively high, it is possible to meet the output power specifications (the power range) when the output power is controlled in accordance with the transfer power control command from the base station to suppress the reduction in quality of the transmission signal output from the power amplifier circuit according to the present modification.

In the power amplifier circuit according to the present modification, the PA control circuit 20 may set the switch 363 to the conductive state (connection of one end of the switch 363 to the other end thereof) when the third radio-frequency input signal is input into the amplifier transistor 12 and may set the switch 363 to the non-conductive state (non-connection of one end of the switch 363 to the other end thereof) when the fourth radio-frequency input signal of a frequency band higher than that of the third radio-frequency input signal is input into the amplifier transistor 12.

In this case, the gain deviation when the output power is varied while ensuring the power-added efficiency and the linearity is capable of being reduced even in the analog ET mode when the third radio-frequency input signal is input into the amplifier transistor 12. Accordingly, it is possible to meet the output power specifications (the power range) when the output power is controlled in accordance with the transfer power control command from the base station to suppress the reduction in quality of the transmission signal output from the power amplifier circuit according to the present modification. In addition, the gain deviation when the output power is varied is capable of being reduced even in the APT mode when the fourth radio-frequency input signal is input into the amplifier transistor 12. Accordingly, it is possible to meet the output power specifications (the power range) when the output power is controlled in accordance with the transfer power control command from the base station to suppress the reduction in quality of the transmission signal output from the power amplifier circuit according to the present modification.

### [2. Mounting Configuration of Radio-Frequency Module 6]

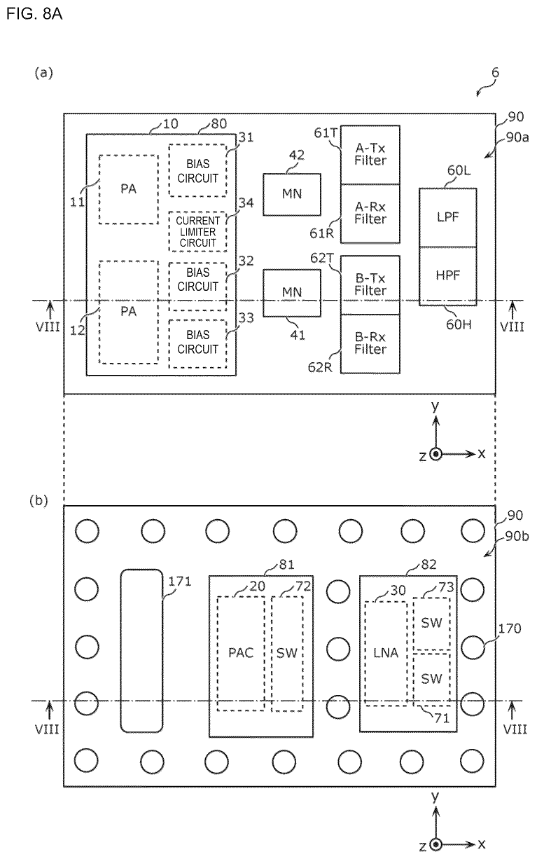

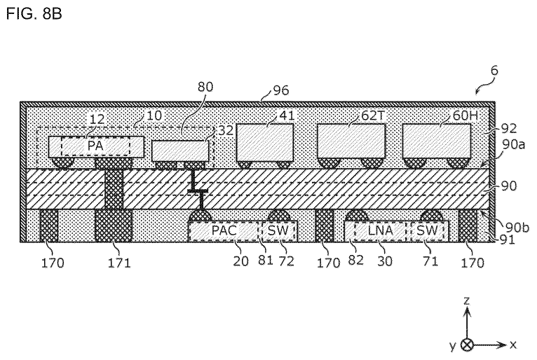

A mounting configuration of the radio-frequency module 6 according to the present exemplary embodiment will now be described with reference to FIG. 8A and FIG. 8B.

FIG. 8A is a plan view of the radio-frequency module 6 according to an example. In FIG. 8A, (a) is a perspective view at a main surface 90a side of a module laminate 90 when viewed from the positive side of the z axis. In FIG. 8A, (b) is a perspective view at a main surface 90b side of the module laminate 90 when viewed from the positive side of the z axis. FIG. 8B is a cross-sectional view of the radio-frequency module 6 according to the example. The cross section of the radio-frequency module 6 in FIG. 8B is a cross section taken along the VIII-VIII line in FIG. 8A.

Although characters representing the respective components may be added to the components for easy understanding of the arrangement relationship of the respective components in FIG. 8A and FIG. 8B, the characters are not practically added to the respective components. In addition, illustration of part of the wiring with which multiple electronic components arranged on the module laminate 90 are connected is omitted in FIG. 8A and FIG. 8B. Furthermore, illustration of resin members 91 and 92 with which the multiple electronic components are covered and a shield electrode layer 96 with which the surfaces of the resin members 91 and 92 are covered is omitted in FIG. 8A.

The radio-frequency module 6 includes the module laminate 90, the resin members 91 and 92, the shield electrode layer 96, multiple post electrodes 170, and a radiation electrode 171, in addition to the multiple electronic components including the multiple circuit elements included in the radio-frequency module 6 illustrated in FIG. 1.

The module laminate 90 has the main surfaces 90a and 90b, which are opposed to each other. The main surfaces 90a and 90b are examples of a first main surface and a second main surface, respectively. Although the module laminate 90 has a rectangular shape in a plan view in FIG. 8A, the shape of the module laminate 90 is not limited to this.

Although, for example, a low temperature co-fired ceramics (LTCC) substrate or a high temperature co-fired ceramics (HTCC) substrate, which have a laminated structure of multiple dielectric layers, a component-embedded board, a substrate including a redistribution layer (RDL), or a printed circuit board may be used as the module laminate 90, the module laminate 90 is not limited to the above ones.

On the main surface 90a, the power amplifier 10, the duplexers 61 and 62, the matching circuits 41 and 42, the diplexer 60, and the resin member 92 are arranged.

On the main surface 90b, the PA control circuit 20, the low noise amplifier 30, the switches 71 to 73, the radiation electrode 171, the post electrodes 170, and the resin member 91 are arranged.

The power amplifier 10 is composed of a semiconductor integrated circuit (IC) 80. The semiconductor IC 80 is one example of a first semiconductor IC.

The semiconductor IC 80 is made of at least one of gallium arsenide (GaAs), silicon germanium (SiGe), and gallium nitride (GaN). Each of the amplifier transistors 11 and 12, the constant current amplifier transistors 310, 320, and 330, and the current limiting transistor 340 included in the power amplifier 10 is a bipolar transistor, such as a heterojunction bipolar transistor (HBT).

The semiconductor IC 80 may be composed of complementary metal oxide semiconductor (CMOS) and, specifically, may be manufactured through a silicon on insulator (SOI) process. In this case, each transistor included in the power amplifier 10 may include a field effect transistor, such as a metal-oxide-semiconductor field effect transistor (MOSFET). The semiconductor material of the semiconductor IC 80 is not limited to the above materials.

The PA control circuit 20 and the switch 72 are included in a semiconductor IC 81. The semiconductor IC 81 is one example of a second semiconductor IC. The low noise amplifier 30 and the switches 71 and 73 are included in a semiconductor IC 82.

Each of the semiconductor ICs 81 and 82 is composed of CMOS and, specifically, is manufactured through the SOI process. Each of the semiconductor ICs 81 and 82 may be made of at least one of GaAs, SiGe, and GaN.

As illustrated in FIG. 8A, in the semiconductor IC 80, the bias circuits 32 and 33 are arranged at positions closer to the semiconductor IC 81 than the amplifier transistor 12.

With the above configuration, since control wiring between the PA control circuit 20 and the bias circuits 32 and 33 is capable of being shortened, the control of the direct-current bias current involved in the switching between the analog ET mode and the APT mode is capable of being performed with high accuracy.

In addition, in the semiconductor IC 80, the bias circuits 32 and 33 are arranged at positions closer to the semiconductor IC 81 than the amplifier transistors 11 and 12 and the current limiter circuit 34 is arranged so as to be closer to the amplifier transistor 11 than the bias circuit 33.

With the above configuration, since the current limiter circuit 34 is capable of being connected so as to be closer to Vcc1, among the collector-side voltages Vcc1 and Vcc2, the voltage value of the collector-side voltage (the power supply voltage Vcc) with small radio-frequency noise is capable of being monitored. As a result, it is possible to accurately generate the direct-current limiting current (−i6).

Each of the duplexers 61 and 62 and the diplexer 60 may be composed of, for example, any of a surface acoustic wave (SAW) filter, a bulk acoustic wave (BAW) filter, an LC resonant filter, and a dielectric filter and is not limited to these filters.

The components on the main surface 90b are covered with the resin member 91. The resin member 91 has a function to ensure the reliabilities, such as the mechanical strength and the moisture resistance, of the components on the main surface 90b. The components on the main surface 90a are covered with the resin member 92. The resin member 92 has a function to ensure the reliabilities, such as the mechanical strength and the moisture resistance, of the components on the main surface 90a.

The multiple post electrodes 170 are multiple external connection terminals including ground terminals, in addition to the antenna connection terminal 100, the input terminal 120, and the control terminal 130 illustrated in FIG. 1. Each of the multiple post electrodes 170 vertically extends from the main surface 90b and passes through the resin member 91. One end of each of the multiple post electrodes 170 reaches the surface of the resin member 91. The multiple post electrodes 170 are connected to input-output terminals, the ground terminals, and/or the likes on a mother board arranged in the negative direction of the z axis of the radio-frequency module 6.

Multiple bump electrodes may be included in the radio-frequency module 6, instead of the multiple post electrodes 170. In this case, the resin member 91 is not necessarily included in the radio-frequency module 6.

The radiation electrode 171 is an electrode for radiating heat generated in the power amplifier 10 to the mother board (not illustrated). At least part of the radiation electrode 171 is overlapped with at least part of the semiconductor IC 80 in a plan view.

The shield electrode layer 96 is a metal thin film formed using, for example, a sputtering method. The shield electrode layer 96 covers the upper surface and the side surfaces of the resin member 92, the side surfaces of the module laminate 90, and the side surfaces of the resin member 91. The shield electrode layer 96 is set to ground potential and is capable of inhibiting external noise from entering the circuit components composing the radio-frequency module 6.

The component arrangement of the radio-frequency module 6 illustrated in FIG. 8A and FIG. 8B is only an example and is not limited to the one illustrated in FIG. 8A and FIG. 8B. For example, the semiconductor ICs 81 and 82 may be arranged on the main surface 90a. In addition, for example, the radio-frequency module 6 does not necessarily include the resin members 91 and 92 and the shield electrode layer 96.

### [3. Exemplary Advantages and so On]

As described above, the power amplifier circuit 1 according to the present exemplary embodiment includes the power supply terminal 140; the amplifier transistor 12 that has the collector terminal 12C connected to the power supply terminal 140, the emitter terminal 12E, and the base terminal 12B and that performs power amplification to the radio-frequency input signal input from the base terminal 12B to output the radio-frequency signal resulting from the power amplification from the collector terminal 12C; the bias circuit 32 that outputs the direct-current bias current i2; the bias circuit 33 that outputs the direct-current bias current i3; and the current limiter circuit 34. The bias circuit 32 includes the constant current amplifier transistor 320 that has the collector terminal, the emitter terminal, and the base terminal and that supplies the direct-current bias current i2 from the emitter terminal to the base terminal 12B. The current limiter circuit 34 includes the current limiting transistor 340 which has the collector terminal, the emitter terminal, and the base terminal and the emitter terminal of which is connected to the emitter terminal of the bias circuit 320, the resistive element 342 connected between the collector terminal of the current limiting transistor 340 and the power supply terminal 140, and the resistive element 341 connected between the base terminal of the current limiting transistor 340 and the base terminal of the constant current amplifier transistor 320. The bias circuit 33 includes the constant current amplifier transistor 330 that has the collector terminal, the emitter terminal, and the base terminal and that supplies the direct-current bias current i3 from the emitter terminal to the base terminal 12B.

When the power supply voltage Vcc is applied to the radio-frequency input signal of a relatively low channel bandwidth, varying the direct-current bias current to be supplied to the amplifier transistor 12 in accordance with the variation in the power supply voltage Vcc enables the gain deviation to be reduced with respect to the variation in the output power. In contrast, when the power supply voltage Vcc is applied to the radio-frequency input signal of a relatively high channel bandwidth, making the direct-current bias current to be supplied to the amplifier transistor 12 constant with respect to the variation in the power supply voltage Vcc enables the gain deviation to be reduced with respect to the variation in the output power. Accordingly, it is possible to suppress the reduction in quality of the transmission signal when the power supply voltage Vcc to be supplied to the power amplifier circuit 1 is varied.

With the above configuration, the magnitude of the direct-current bias current i2 supplied from the bias circuit 32 is varied with the magnitude of the power supply voltage Vcc due to the current limiter circuit 34. In contrast, the magnitude of the direct-current bias current i3 supplied from the bias circuit 33 is not varied in response to the variation in the magnitude of the power supply voltage Vcc. Accordingly, the power supply voltage Vcc is capable of varying the supply specifications of the direct-current bias current to be supplied to the amplifier transistor 12 in accordance with the magnitude of the channel bandwidth. Consequently, it is possible to suppress the reduction in quality of the transmission signal when the ET method is applied.

For example, the power amplifier circuit 1 may further include the PA control circuit 20 that switches between the supply of the direct-current bias current i2 to the base terminal 12B and the supply of the direct-current bias current i3 to the base terminal 12B in accordance with the channel bandwidth of the radio-frequency input signal.

With the above configuration, the power amplifier circuit 1 is capable of switching the supply specifications of the direct-current bias current to be supplied to the amplifier transistor 12 in accordance with the magnitude of the channel bandwidth.

The power amplifier circuit 1 according to the present exemplary embodiment includes the power supply terminal 140; the amplifier transistor 12 to which the power supply voltage Vcc is supplied from the power supply terminal 140 and which performs power amplification to a radio-frequency input signal; the bias circuit 32 that supplies the direct-current bias current i2 to the amplifier transistor 12; the bias circuit 33 that supplies the direct-current bias current i3 to the amplifier transistor 12; the current limiter circuit 34 that is connected to the bias circuit 32 and the amplifier transistor 12 and that varies the magnitude of the direct-current bias current i2 in accordance with the magnitude of the power supply voltage Vcc; and the PA control circuit 20 that switches between the supply of the direct-current bias current i2 to the amplifier transistor 12 and the supply of the direct-current bias current i3 to the amplifier transistor 12 in accordance with the channel bandwidth of the radio-frequency input signal.

With the above configuration, the magnitude of the direct-current bias current i2 supplied from the bias circuit 32 is varied with the magnitude of the power supply voltage Vcc due to the current limiter circuit 34. In contrast, the magnitude of the direct-current bias current i3 supplied from the bias circuit 33 is not varied in response to the variation in the magnitude of the power supply voltage Vcc. Accordingly, the supply specifications of the direct-current bias current to be supplied to the amplifier transistor 12 are capable of being varied in accordance with the magnitude of the channel bandwidth. Consequently, it is possible to suppress the reduction in quality of the transmission signal when the power supply voltage to be supplied to the power amplifier circuit 1 is varied.

For example, in the power amplifier circuit 1, the PA control circuit 20 may cause the bias circuit 32 to supply the direct-current bias current i2 to the amplifier transistor 12 in the analog ET mode in which the power supply voltage Vcc is varied in a continuous voltage level in accordance with the envelope of the radio-frequency input signal and may cause the bias circuit 33 to supply the direct-current bias current i3 to the amplifier transistor 12 in the APT mode in which the power supply voltage Vcc is varied in multiple discrete voltage levels in accordance with the average output power of the power amplifier circuit 1.

With the above configuration, the supply specifications of the direct-current bias current to be supplied to the amplifier transistor 12 are capable of being varied depending on whether the power supply voltage Vcc is controlled in the analog ET mode or in the APT mode. Accordingly, it is possible to suppress the reduction in quality of the transmission signal when the power supply voltage to be supplied to the power amplifier circuit 1 is varied.

For example, in the power amplifier circuit 1, the PA control circuit 20 may cause the bias circuit 32 and the current limiter circuit 34 to supply the direct-current bias current to the base terminal 12B when the first radio-frequency input signal of the first channel bandwidth is input into the amplifier transistor 12 and may cause the bias circuit 33 to supply the direct-current bias current to the base terminal 12B when the second radio-frequency input signal of the second channel bandwidth wider than the first channel bandwidth is input into the amplifier transistor 12.

With the above configuration, since the gain difference when the output power is varied while ensuring the power-added efficiency and the linearity is capable of being reduced when the first radio-frequency input signal is input into the amplifier transistor 12, it is possible to suppress the reduction in amplification characteristics of the power amplifier circuit 1. Since the gain deviation when the power supply voltage Vcc and the output power are varied is capable of being reduced when the second radio-frequency input signal is input into the amplifier transistor 12, it is possible to suppress the reduction in quality of the transmission signal output from the power amplifier circuit 1.

For example, in the power amplifier circuit 1, the PA control circuit 20 may cause the bias circuit 32 and the current limiter circuit 34 to supply the direct-current bias current to the base terminal 12B when the third radio-frequency input signal is input into the amplifier transistor 12 and may cause the bias circuit 33 to supply the direct-current bias current to the base terminal 12B when the fourth radio-frequency input signal of a frequency band higher than that of the third radio-frequency input signal is input into the amplifier transistor 12.

With the above configuration, since the gain difference when the output power is varied while ensuring the power-added efficiency and the linearity is capable of being reduced in the analog ET mode when the third radio-frequency input signal is input into the amplifier transistor 12, it is possible to suppress the reduction in amplification characteristics of the power amplifier circuit 1. Since the gain deviation when the output power is varied is capable of being reduced in the APT mode when the fourth radio-frequency input signal is input into the amplifier transistor 12, it is possible to suppress the reduction in quality of the transmission signal output from the power amplifier circuit 1.

For example, the power amplifier circuit 1 may include the multiple amplifier transistors that include the amplifier transistor 12 and that are cascade-connected to each other.

For example, in the power amplifier circuit 1, the amplifier transistor 12 may be arranged at the last stage in the multiple amplifier transistors.

With the above configuration, it is possible to suppress the reduction in quality of the transmission signal when the power supply voltage to be supplied to the power amplifier circuit 1 is varied.

For example, in the power amplifier circuit 1, the current limiter circuit 34 and the bias circuit 33 may be connected on the path between the output terminal of the amplifier transistor 11 and the input terminal of the amplifier transistor 12 in this order from the side closer to the amplifier transistor 11.

With the above configuration, since the current limiter circuit 34 is connected so as to be closer to Vcc1, among the collector-side voltages Vcc1 and Vcc2, the voltage value of the collector-side voltage (the power supply voltage Vcc) with small radio-frequency noise is capable of being monitored. As a result, it is possible to accurately generate the direct-current limiting current (−i6).

For example, the power amplifier circuit 1 may further include the module laminate 90 that has the main surfaces 90a and 90b that are opposed to each other. The semiconductor IC 80 including the amplifier transistor 12, the bias circuit 32, the current limiter circuit 34, and the bias circuit 33 may be arranged on the main surface 90a. The semiconductor IC 81 including the PA control circuit 20 controlling the amplifier transistor 12 and the bias circuits 32 and 33 may be arranged on the main surface 90b. In the semiconductor IC 80, the bias circuit 32 and 33 may be arranged at positions closer to the semiconductor IC 81 than the amplifier transistor 12.

With the above configuration, since the control wiring between the PA control circuit 20 and the bias circuits 32 and 33 is capable of being shortened, the control of the direct-current bias current involved in the magnitude of the channel bandwidth of the radio-frequency input signal is capable of being performed with high accuracy.

For example, the power amplifier circuit 1 may further include the module laminate 90 that has the main surface 90a and 90b that are opposed to each other. The semiconductor IC 80 including the amplifier transistors 11 and 12, the bias circuits 32 and 33, and the current limiter circuit 34 may be arranged on the main surface 90a. The semiconductor IC 81 including the PA control circuit 20 controlling the amplifier transistors 11 and 12 and the bias circuits 32 and 33 may be arranged on the main surface 90b. In the semiconductor IC 80, the bias circuits 32 and 33 may be arranged at positions closer to the semiconductor IC 81 than the amplifier transistors 11 and 12. The current limiter circuit 34 may be arranged so as to be closer to the amplifier transistor 11 than the bias circuit 33.

With the above configuration, since the current limiter circuit 34 is capable of being connected so as to be closer to Vcc1, among the collector-side voltages Vcc1 and Vcc2, the voltage value of the collector-side voltage (the power supply voltage Vcc) with small radio-frequency noise is capable of being monitored. As a result, it is possible to accurately generate the direct-current limiting current (−i6).

The power amplifier circuit according to the modification includes the power supply terminal 140; the amplifier transistor 12 that has the collector terminal 12C connected to the power supply terminal 140, the emitter terminal 12E, and the base terminal 12B and that performs power amplification to the radio-frequency input signal input from the base terminal 12B to output the radio-frequency signal resulting from the power amplification from the collector terminal 12C; the bias circuit 32 that outputs the direct-current bias current i2; and the current limiter circuit 36. The bias circuit 32 includes the constant current amplifier transistor 320 that has the collector terminal, the emitter terminal, and the base terminal and that supplies the direct-current bias current i2 from the emitter terminal to the base terminal 12B. The current limiter circuit 36 includes the current limiting transistor 360 that has the collector terminal, the emitter terminal, and the base terminal, the resistive element 362 connected between the collector terminal of the current limiting transistor 360 and the power supply terminal 140, the resistive element 361 connected between the base terminal of the current limiting transistor 360 and the base terminal of the constant current amplifier transistor 320, and the switch 363 one end of which is connected to the emitter terminal of the current limiting transistor 360 and the other end of which is connected to the emitter terminal of the constant current amplifier transistor 320.

With the above configuration, the magnitude of the direct-current bias current i2 supplied from the bias circuit 32 is varied with the magnitude of the power supply voltage Vcc in response to the switching of the switch 363 in the current limiter circuit 36. Accordingly, the supply specifications of the direct-current bias current to be supplied to the amplifier transistor 12 are capable of being varied in accordance with the magnitude of the channel bandwidth. Consequently, it is possible to suppress the reduction in quality of the transmission signal when the power supply voltage to be supplied to the power amplifier circuit is varied.

For example, the power amplifier circuit according to the modification may further include the PA control circuit 20 that switches between the conductive state and the non-conductive state of the switch 363 in accordance with the channel bandwidth of the radio-frequency input signal.

With the above configuration, the supply specifications of the direct-current bias current to be supplied to the amplifier transistor 12 are capable of being varied in accordance with the magnitude of the channel bandwidth.

For example, in the power amplifier circuit according to the modification, the PA control circuit 20 may set the switch 363 to the conductive state in the analog ET mode and may set the switch 363 to the non-conductive state in the APT mode.

With the above configuration, the supply specifications of the direct-current bias current to be supplied to the amplifier transistor 12 are capable of being varied depending on whether the power supply voltage Vcc is controlled in the analog ET mode or in the APT mode. Accordingly, it is possible to suppress the reduction in quality of the transmission signal due to the switching of the supply mode of the power supply voltage to be supplied to the power amplifier circuit.

For example, in the power amplifier circuit according to the modification, the PA control circuit 20 may set the switch 363 to the conductive state when the first radio-frequency input signal of the first channel bandwidth is input into the amplifier transistor 12 and may set the switch 363 to the non-conductive state when the second radio-frequency input signal of the second channel bandwidth wider than the first channel bandwidth is input into the amplifier transistor 12.

With the above configuration, since the gain deviation when the output power is varied while ensuring the power-added efficiency and the linearity is capable of being reduced when the first radio-frequency input signal is input into the amplifier transistor 12, it is possible to suppress the reduction in quality of the transmission signal of the power amplifier circuit according to the present modification. Since the gain deviation when the output power is varied is capable of being reduced when the second radio-frequency input signal is input into the amplifier transistor 12, it is possible to suppress the reduction in quality of the transmission signal of the power amplifier circuit according to the present modification.

For example, in the power amplifier circuit according to the modification, the PA control circuit 20 may set the switch 363 to the conductive state when the third radio-frequency input signal is input into the amplifier transistor 12 and may set the switch 363 to the non-conductive state when the fourth radio-frequency input signal of the frequency band higher than that of the third radio-frequency input signal is input into the amplifier transistor 12.

With the above configuration, since the gain deviation when the output power is varied while ensuring the power-added efficiency and the linearity is capable of being reduced in the analog ET mode when the third radio-frequency input signal is input into the amplifier transistor 12, it is possible to suppress reduction in quality of the transmission signal output from the power amplifier circuit according to the present modification. Since the gain deviation when the output power is varied is capable of being reduced in the APT mode when the fourth radio-frequency input signal is input into the amplifier transistor 12, it is possible to suppress the reduction in quality of the transmission signal output from the power amplifier circuit according to the present modification.

The communication device 7 according to the present exemplary embodiment includes the RFIC 3 that processes the radio-frequency signal and the power amplifier circuit 1 that transmits the radio-frequency signal between the RFIC 3 and the antenna 2.

With the above configuration, it is possible to realize the exemplary advantages of the power amplifier circuit 1 in the communication device 7.

For example, the communication device 7 may further include the power supply circuit 5 that supplies the power supply voltage Vcc to the power amplifier circuit 1. The power supply circuit 5 may include the power supply control circuit 50 that controls the power supply voltage Vcc so as to a linear function of the power amplitude of the radio-frequency signal.

With the above configuration, it is sufficient to monitor the power supply voltage Vcc, which has linear relationship (the linear function) with the power level, instead of monitoring of the power level of the radio-frequency signal, to operate the current limiter circuit 34. Accordingly, it is possible to simplify the circuit configuration of the current limiter circuit 34.

### OTHER EMBODIMENTS

Although the power amplifier circuit and the communication device according to the present disclosure are described above using the exemplary embodiment, the power amplifier circuit and the communication device according to the present disclosure are not limited to the above exemplary embodiment. Other exemplary embodiments realized by combining arbitrary components in the above exemplary embodiment, modifications resulting from making various modifications supposed by the person skilled in the art to the above exemplary embodiment without departing from the sprit and scope of the present disclosure, and various devices incorporating the power amplifier circuit and the communication device are also included in the present disclosure.

For example, other circuit elements, wiring, and so on may be provided between the paths with which the respective circuit elements and the signal paths disclosed in the drawings are connected in the circuit configuration of the power amplifier circuit and the communication device according to the above exemplary embodiment.

### INDUSTRIAL APPLICABILITY

The present disclosure is widely usable for a communication device, such as a mobile phone, as the power amplifier circuit or the communication device arranged in a multiband front end unit.

### REFERENCE SIGNS LIST

1 power amplifier circuit
2 antenna
3 RFIC
4 BBIC
5 power supply circuit
6 radio-frequency module
7 communication device
10, 15 power amplifier
11, 12 amplifier transistor
11B, 12B base terminal
11C, 12C collector terminal
11E, 12E emitter terminal
20 PA control circuit
30 low noise amplifier
31, 32, 33 bias circuit
34, 36 current limiter circuit
41, 42 matching circuit
50 power supply control circuit
51 analog ET tracker
52 APT tracker
53, 71, 72, 73, 363 switch
54 power supply
60 diplexer
60H high pass filter
60L low pass filter
61, 62 duplexer
61R, 62R reception filter
61T, 62T transmission filter
71a, 71b, 71c, 72a, 72b, 72c, 73a, 73b, 73c terminal
80, 81, 82 semiconductor IC
90 module laminate
90a, 90b main surface
91, 92 resin member
96 shield electrode layer
100 antenna connection terminal
110 output terminal
120 input terminal
130 control terminal
140 power supply terminal
141, 142, 143, 313, 323, 333 capacitor
151, 152, 153, 314, 324, 334, 341, 342, 361, 362 resistive element
161 impedance matching circuit
170 post electrode
171 radiation electrode
310, 320, 330 constant current amplifier transistor
311, 312, 321, 322, 331, 332 transistor
315, 325, 335 constant current source
340, 360 current limiting transistor

1. A power amplifier circuit comprising:
a power supply terminal;
a first amplifier transistor that has a first terminal connected to the power supply terminal, a second terminal, and a first control terminal and that performs power amplification to a radio-frequency input signal input from the first control terminal to output a radio-frequency signal resulting from the power amplification from the first terminal;
a first bias circuit that outputs first direct-current bias current;
a second bias circuit that outputs second direct-current bias current; and
a modulation circuit,
wherein the first bias circuit includes
a first transistor that has a third terminal, a fourth terminal, and a second control terminal and that supplies the first direct-current bias current from the fourth terminal to the first control terminal,
wherein the modulation circuit includes
a second transistor which has a fifth terminal, a sixth terminal, and a third control terminal and the sixth terminal of which is connected to the fourth terminal,
a first resistive element connected between the fifth terminal and the power supply terminal, and
a second resistive element connected between the third control terminal and the second control terminal, and
wherein the second bias circuit includes
a third transistor that has a seventh terminal, an eighth terminal, and a fourth control terminal and that supplies the second direct-current bias current from the eighth terminal to the first control terminal.

2. The power amplifier circuit according to claim 1, further comprising:
a control circuit that switches between the supply of the first direct-current bias current to the first control terminal and the supply of the second direct-current bias current to the first control terminal in accordance with a channel bandwidth of the radio-frequency input signal.

3. A power amplifier circuit comprising:
a power supply terminal;
a first amplifier transistor to which power supply voltage is supplied from the power supply terminal and which performs power amplification to a radio-frequency input signal;
a first bias circuit that supplies first direct-current bias current to the first amplifier transistor;
a second bias circuit that supplies second direct-current bias current to the first amplifier transistor;
a modulation circuit that is connected to the first bias circuit and the first amplifier transistor and that varies a magnitude of the first direct-current bias current in accordance with a magnitude of the power supply voltage; and
a control circuit that switches between the supply of the first direct-current bias current to the first amplifier transistor and the supply of the second direct-current bias current to the first amplifier transistor in accordance with a channel bandwidth of the radio-frequency input signal.

4. The power amplifier circuit according to claim 2,
wherein, in an analog envelope tracking mode in which the power supply voltage applied to the power supply terminal is varied in a continuous voltage level in accordance with an envelope of the radio-frequency input signal, the control circuit causes the first bias circuit to supply the first direct-current bias current to the first amplifier transistor, and
wherein, in an average power tracking mode in which the power supply voltage is varied in multiple discrete voltage levels in accordance with average output power of a radio-frequency signal, the control circuit causes the second bias circuit to supply the second direct-current bias current to the first amplifier transistor.

5. The power amplifier circuit according to claim 2,
wherein a first radio-frequency input signal of a first channel bandwidth and a second radio-frequency input signal of a second channel bandwidth wider than the first channel bandwidth are input into the first amplifier transistor,
wherein, in a case that the first radio-frequency input signal is input into the first amplifier transistor, the control circuit causes the first bias circuit to supply the first direct-current bias current to the first amplifier transistor, and
wherein, in a case that the second radio-frequency input signal is input into the first amplifier transistor, the control circuit causes the second bias circuit to supply the second direct-current bias current to the first amplifier transistor.

6. The power amplifier circuit according to claim 2,
wherein a third radio-frequency input signal and a fourth radio-frequency input signal of a frequency band higher than that of the third radio-frequency input signal are input into the first amplifier transistor,
wherein, in a case that the third radio-frequency input signal is input into the first amplifier transistor, the control circuit causes the first bias circuit to supply the first direct-current bias current to the first amplifier transistor, and
wherein, in a case that the fourth radio-frequency input signal is input into the first amplifier transistor, the control circuit causes the second bias circuit to supply the second direct-current bias current to the first amplifier transistor.

7. The power amplifier circuit according to claim 1,
wherein the power amplifier circuit includes a plurality of amplifier transistors that includes the first amplifier transistor and that is cascade-connected to each other.

8. The power amplifier circuit according to claim 7,
wherein the first amplifier transistor is arranged at a last stage in the plurality of amplifier transistors.

9. The power amplifier circuit according to claim 7,
wherein the plurality of amplifier transistors includes the first amplifier transistor, and
a second amplifier transistor arranged at a previous state of the first amplifier transistor, and
wherein the modulation circuit and the second bias circuit are connected on a path between an output terminal of the second amplifier transistor and an input terminal of the first amplifier transistor in this order from the side closer to the second amplifier transistor.

10. The power amplifier circuit according to claim 1, further comprising:
a module laminate that has a first main surface and a second main surface that are opposed to each other,
wherein a first semiconductor integrated circuit including the first amplifier transistor, the first bias circuit, the modulation circuit, and the second bias circuit is arranged on the first main surface,
wherein a second semiconductor integrated circuit including the control circuit controlling the first amplifier transistor, the first bias circuit, and the second bias circuit is arranged on the second main surface, and
wherein, in the first semiconductor integrated circuit, the first bias circuit and the second bias circuit are arranged at positions closer to the second semiconductor integrated circuit than the first amplifier transistor.

11. The power amplifier circuit according to claim 9, further comprising:
a module laminate that has a first main surface and a second main surface that are opposed to each other,
wherein a first semiconductor integrated circuit including the first amplifier transistor, the second amplifier transistor, the first bias circuit, the modulation circuit, and the second bias circuit is arranged on the first main surface,
wherein a second semiconductor integrated circuit including the control circuit controlling the first amplifier transistor, the second amplifier transistor, the first bias circuit, and the second bias circuit is arranged on the second main surface,
wherein, in the first semiconductor integrated circuit, the first bias circuit and the second bias circuit are arranged at positions closer to the second semiconductor integrated circuit than the first amplifier transistor and the second amplifier transistor, and
wherein the modulation circuit is arranged so as to be closer to the second amplifier transistor than the second bias circuit.

12. A power amplifier circuit comprising:
a power supply terminal;
a first amplifier transistor that has a first terminal connected to the power supply terminal, a second terminal, and a first control terminal and that performs power amplification to a radio-frequency input signal input from the first control terminal to output a radio-frequency signal resulting from the power amplification from the first terminal;
a first bias circuit that outputs first direct-current bias current; and
a modulation circuit,
wherein the first bias circuit includes
a first transistor that has a third terminal, a fourth terminal, and a second control terminal and that supplies the first direct-current bias current from the fourth terminal to the first control terminal, and
wherein the modulation circuit includes
a second transistor that has a fifth terminal, a sixth terminal, and a third control terminal,
a first resistive element connected between the fifth terminal and the power supply terminal,
a second resistive element connected between the third control terminal and the second control terminal, and
a first switch which has a seventh terminal and an eighth terminal, the seventh terminal of which is connected to the sixth terminal, and the eighth terminal of which is connected to the fourth terminal.

13. The power amplifier circuit according to claim 12, further comprising:
a control circuit that switches between connection between the seventh terminal and the eighth terminal and non-connection therebetween in accordance with a channel bandwidth of the radio-frequency input signal.

14. The power amplifier circuit according to claim 13,
wherein, in an analog envelope tracking mode in which the power supply voltage applied to the power supply terminal is varied in a continuous voltage level in accordance with an envelope of the radio-frequency input signal, the control circuit connects the seventh terminal to the eighth terminal, and
wherein, in an average power tracking mode in which the power supply voltage is varied in multiple discrete voltage levels in accordance with average output power of a radio-frequency signal, the control circuit does not connect the seventh terminal to the eighth terminal.

15. The power amplifier circuit according to claim 13,
wherein a first radio-frequency input signal of a first channel bandwidth and a second radio-frequency input signal of a second channel bandwidth wider than the first channel bandwidth are input into the first amplifier transistor,
wherein, in a case that the first radio-frequency input signal is input into the first amplifier transistor, the control circuit connects the seventh terminal to the eighth terminal, and
wherein, in a case that the second radio-frequency input signal is input into the first amplifier transistor, the control circuit does not connect the seventh terminal to the eighth terminal.

16. The power amplifier circuit according to claim 13,
wherein a third radio-frequency input signal and a fourth radio-frequency input signal of a frequency band higher than that of the third radio-frequency input signal are input into the first amplifier transistor,
wherein, in a case that the third radio-frequency input signal is input into the first amplifier transistor, the control circuit connects the seventh terminal to the eighth terminal, and
wherein, in a case that the fourth radio-frequency input signal is input into the first amplifier transistor, the control circuit does not connect the seventh terminal to the eighth terminal.

17. A communication device comprising:
a signal processing circuit that processes a radio-frequency signal; and
the power amplifier circuit according to claim 1, which transmits the radio-frequency signal between the signal processing circuit and an antenna.

18. The communication device according to claim 17, further comprising:
a power supply circuit that supplies power supply voltage to the power amplifier circuit,
wherein the power supply circuit includes a power supply control circuit that controls the power supply voltage so as to be a linear function of power amplitude of the radio-frequency signal.

19. The power amplifier according to claim 10, wherein the module laminate includes a low-temperature co-fired ceramic (LTCC).

20. The power amplifier according to claim 10, wherein the module laminate includes a high-temperature co-fired ceramic (HTCC).
